(19) United States
(12) Patent Application Publication
(10) Pub. No.: US 2025/0105865 A1
(43) Pub. Date: Mar. 27, 2025

(54) TRANSMITTER ADAPTIVELY SELECTING DIGITAL PREDISTORTION MODE, DIGITAL PREDISTORTER AND TRAINING METHOD THEREOF

(71) Applicant: SAMSUNG ELECTRONICS CO., LTD., SUWON-SI (KR)

(72) Inventors: YOUNGSUB KIM, Suwon-si (KR); HONGMIN CHOI, Suwon-si (KR); HYUNG SUN LIM, Suwon-si (KR)

(21) Appl. No.: 18/613,248

(22) Filed: Mar. 22, 2024

(30) Foreign Application Priority Data
Sep. 27, 2023 (KR) 10-2023-0131067

(51) Int. Cl. H04B 1/04

(52) U.S. Cl. CPC H04B 1/0475; H04B 1/0483; H04B 2001/0425

(57) ABSTRACT

Disclosed is a transmitting device, comprising, a multi-mode digital predistorter circuit configured to pre-compensate an input baseband signal in one of a plurality of digital predistortion modes according to a selection signal, a power amplifier configured to amplify the pre-compensated baseband signal and output the amplified baseband signal as an output signal of an allocated band, and a digital predistortion mode selector circuit configured to determine the one of the plurality of digital predistortion modes corresponding to the allocated band using a feedback signal obtained from the output signal, and set the multi-mode digital predistorter circuit to the one of the determined modes.

### CROSS-REFERENCE TO RELATED APPLICATION

This application claims priority under 35 U.S.C. § 119 to Korean Patent Application No. 10-2023-0131067 filed on Sep. 27, 2023 in the Korean Intellectual Property Office, the disclosure of which is incorporated by reference herein in its entirety.

### TECHNICAL FIELD

Embodiments of the present disclosure described herein relate generally to communication devices and more specifically to a transmitting device that pre-distorts signals input to a power amplifier; a digital predistorter; and a training method thereof.

### DISCUSSION OF RELATED ART

Power amplifiers within transmitters may be biased to achieve high efficiency, but at the expense of nonlinear operation in which signal quality deteriorates. To counteract such signal quality deterioration, a digital predistortion (DPD) technique may be used to adjust the input signal in a manner complementary to the nonlinear characteristics of the amplifier and achieve a substantially linearized amplification system. Nevertheless, even with such a pre-distorted input signal, it is difficult to secure an overall linearity of the amplification system. As a result, performance parameters such as adjacent channel leakage ratio (ACLR) and error vector magnitude (EVM) may be degraded.

Accordingly, a need exists for improvements in digital predistortion technology to ensure linearity while maintaining high efficiency characteristics of a nonlinear power amplifier, such as a Doherty power amplifier employed in a mobile device.

### SUMMARY

According to an embodiment, a transmitting device includes: a multi-mode digital predistorter circuit configured to pre-compensate an input baseband signal in one of a plurality of digital predistortion modes according to a selection signal; a power amplifier configured to amplify the pre-compensated baseband signal and output the amplified baseband signal as an output signal of an allocated band; and a digital predistortion mode selector circuit configured to determine the one of the plurality of digital predistortion modes corresponding to the allocated band using a feedback signal obtained from the output signal, and set the multi-mode digital predistorter circuit to the one of the determined modes.

According to an embodiment, a predistortion method of a digital predistorter to compensate for nonlinearity of a power amplifier includes: evaluating the performance of the digital predistorter in each of a plurality of digital predistortion modes, selecting one of the plurality of digital predistortion modes based on the evaluated performance; and setting the digital predistorter to any one of the selected modes, wherein the digital predistorter comprises, first kernel processing circuitry (“first kernel”) configured to process an input baseband signal in one of a memoryless polynomial mode and a memory polynomial mode in response to a first enable signal, second kernel processing circuitry (“second kernel”) configured to perform an operation of the dynamic deviation reduction mode on the input baseband signal in response to a second enable signal, and an adder configured to add a first term signal output from the first kernel and a second term signal output from the second kernel to provide a pre-compensated baseband signal in the dynamic deviation reduction mode.

According to an embodiment, a digital predistorter to pre-compensate for nonlinearity in a power amplifier includes: a first kernel configured to process an input baseband signal in one of a memoryless polynomial mode and a memory polynomial mode in response to a first enable signal, a second kernel configured to perform some operation in a dynamic deviation reduction mode on the input baseband signal in response to a second enable signal, an adder configured to add a first term signal output from the first kernel and a second term signal output from the second kernel to provide a pre-compensated baseband signal in the dynamic deviation reduction mode, and a selector configured to select one of the first term signal and an output of the adder in response to a selection signal,
wherein the first term signal corresponds to

$${\sum }_{k = 0}^{K - 1} {\sum }_{m = 0}^{M - 1} {a}_{k , m} {\vert x ( n - m ) \vert}^{k} x ( n - m ) ,$$

where a_{k,m} represents a polynomial coefficient of a diagonal term, M is a maximum order of memory length, K is a non-linear order, and m is a memory depth, and the second term signal corresponds to

$${\sum }_{k = 1}^{K - 1} {\sum }_{l = 1}^{L - 1} {b}_{k , l} {\vert x ( n ) \vert}^{2 ( k - 1 )} {x}^{2} ( n ) {x}^{*} ( n - l ) ,$$

where b_{k,l} is a polynomial coefficient of an off-diagonal term, and x*(n−1) is a complex conjugate of x(n−1).

### BRIEF DESCRIPTION OF THE FIGURES

The above and other aspects and features of the present disclosure will become apparent by describing in detail embodiments thereof with reference to the accompanying drawings, in which:

FIG. 1 is a block diagram showing a transmitting device according to an embodiment of the present disclosure.

FIG. 2 is a block diagram illustrating an embodiment of the transmitting device of FIG. 1.

FIG. 3 is a block diagram showing the structure of the multi-mode digital predistorter of FIG. 1 or FIG. 2.

FIG. 4 is a diagram briefly showing example operation characteristics of the multi-mode digital predistorter of the present disclosure.

FIG. 5 is a table showing the types of processing operations for each DPD operation mode of the multi-mode digital predistorter of the present disclosure.

FIG. 6 is a block diagram showing the operation method of the first kernel and the second kernel of the present disclosure.

FIG. 7 is a flow chart showing the setting procedure of the multi-mode digital predistorter performed during the training operation of the transmitter of the present disclosure.

FIG. 8 is a flowchart showing a setting procedure for a multi-mode digital predistorter performed during a training operation of a transmitter according to another embodiment of the present disclosure.

FIG. 9 is a block diagram showing a transmitting device with a multi-mode digital predistorter according to another embodiment of the present disclosure.

FIG. 10 shows the adjacent channel leakage ratio ACLR performance in the mid-high band MHB of the multi-mode digital predistorter of the present disclosure.

FIG. 11 shows the adjacent channel leakage ratio ACLR performance of the multi-mode digital predistorter of the present disclosure in the ultra-high band UHB.

FIG. 12 is a block diagram showing a mobile device transmitting a transmission signal in multiple bands according to another embodiment of the present disclosure.

### DETAILED DESCRIPTION

Hereinafter, embodiments of the present disclosure will be described with reference to the accompanying drawings in order to describe in enough detail for those skilled in the art to readily implement the technical idea of the present disclosure.

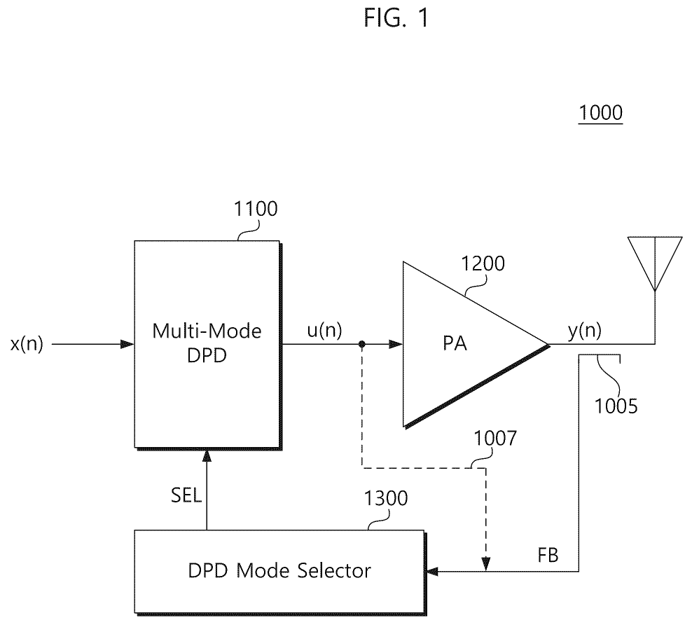

FIG. 1 is a block diagram showing a transmitting device, 1000, according to an embodiment of the present disclosure. Referring to FIG. 1, the transmitting device 1000 may include a power amplifier 1200, and respective circuits (e.g., processing circuitry) forming a multi-mode digital predistorter (DPD) circuit 1100 and a digital predistorter (DPD) mode selector circuit 1300 (“DPD mode selector 1300”). Here, the multi-mode digital predistorter 1100 operates in one of a plurality of digital predistortion (hereinafter also referred to as DPD) modes according to a transmission frequency band, bias setting of the power amplifier 1200, and/or various operating environments.

The multi-mode digital predistorter circuit 1100 (interchangeably hereafter, “DPD 1100” or “multi-mode digital predistorter 1100”) performs a digital predistortion operation to pre-compensate for the nonlinearity of the power amplifier 1200. The DPD 1100 performs filtering/dynamic amplitude adjustment on an input baseband signal x(n) (in a discrete time system), which is a pre-compensation for the nonlinear characteristics of the power amplifier 1200, and provides the input baseband signal x(n) to the power amplifier 1200. The DPD 1100 performs digital operations to compensate for the nonlinear characteristics and resulting distortion of the power amplifier 1200. In general, a digital predistorter may be implemented by modeling the inverse function of the output function of the power amplifier 1200. However, the power amplifier 1200 may operate effectively only in certain operating environments. Accordingly, the DPD 1100 of the present disclosure can execute a digital predistortion (DPD) mode optimized for the transmission band or bias setting of the power amplifier 1200. (Note that the transmission band of the power amplifier 1200 may be a microwave band or a millimeter wave band, and the power amplifier 1200 may include an upconverter, a local oscillator, etc. for upconverting the baseband signal u (n) to the microwave or millimeter wave band.)

The DPD mode driven by the DPD 1100 may be derived through behavior modeling based on the Volterra series. Examples of the DPD mode may include a memoryless (ML) polynomial mode, a memory polynomial (MP) mode, and a dynamic deviation reduction (DDR) mode.

Memory polynomial (MP) mode uses a digital predistortion model that considers an “off-diagonal” term of the Volterra series. The MP mode considers that a power amplifier may exhibit memory effects, in which the amplifier's current output signal is a function of both the current input signal and previous input signal values. Memoryless (ML) polynomial mode may consider only the current input signal and uses a model that removes the memory effect due to previous input signals. The dynamic deviation reduction DDR mode uses a motion model that combines additional terms to compensate for the off-diagonal term that is not sufficiently considered in the MP model.

The multi-mode digital predistorter (DPD) 1100 of the present disclosure has a kernel structure similar to a dynamic deviation reduction (DDR) model. However, the DPD mode selector 1300 can switch the multi-mode digital predistorter 1100 to any DPD mode among ML polynomial mode, MP mode, and DDR mode. The multi-mode digital predistorter 1100 may include first kernel processing circuitry (a “first kernel”) responsible for a first term for processing the ML polynomial mode and the MP mode. However, the first term of the Volterra series processed by the first kernel of the present disclosure is different from the polynomial form of a general MP mode. This will be explained in more detail with reference to the mathematical equations described later. Further, the multi-mode digital predistorter 1100 may include second kernel processing circuitry (a “second kernel”) that processes the second term corresponding to the off-diagonal term.

Here, the first kernel performs an operation in the ML polynomial mode or the MP mode according to the selection signal SEL. On the other hand, the second kernel may be activated or deactivated according to the selection signal SEL. If the multi-mode digital predistorter 1100 operates in dynamic deviation reduction DDR mode, the memory polynomial MP mode of the first kernel and the second kernel may be activated. By adding the output signals of the first kernel and the second kernel, the DPD 1100 can operate in dynamic deviation reduction DDR mode.

On the other hand, when the DPD 1100 operates in ML polynomial mode, the first kernel is activated under a specific condition (the condition in which the memory depth is set to ‘0’), and the second kernel is deactivated. Then, the predistortion signal u (n) output from the first kernel can provide digital predistortion characteristics corresponding to the ML polynomial mode. Additionally, if the DPD 1100 is to operate in MP mode, the MP mode of the first kernel is activated and the second kernel is deactivated. Then, the signal output from the first kernel may provide digital predistortion characteristics corresponding to the MP mode.

The power amplifier 1200 may be a high-efficiency Doherty power amplifier that can be applied to the transmission device 1000. The Doherty power amplifier can use a bias setting method to improve efficiency. In conventional transmission devices employing a Doherty power amplifier, it is difficult to secure the linearity of the amplification chain, which may result in deterioration of adjacent channel leakage ratio (ACLR) or error vector magnitude (EVM) performance. By contrast, the multi-mode digital predistorter 1100 of the present disclosure is a circuit used to secure linearity of the amplification chain while maintaining the high efficiency characteristics of the power amplifier 1200. Here, the power amplifier 1200 is not limited to the Doherty power amplifier and may be any of a variety of power amplifiers that benefit from pre-compensation for non-linearity or distortion.

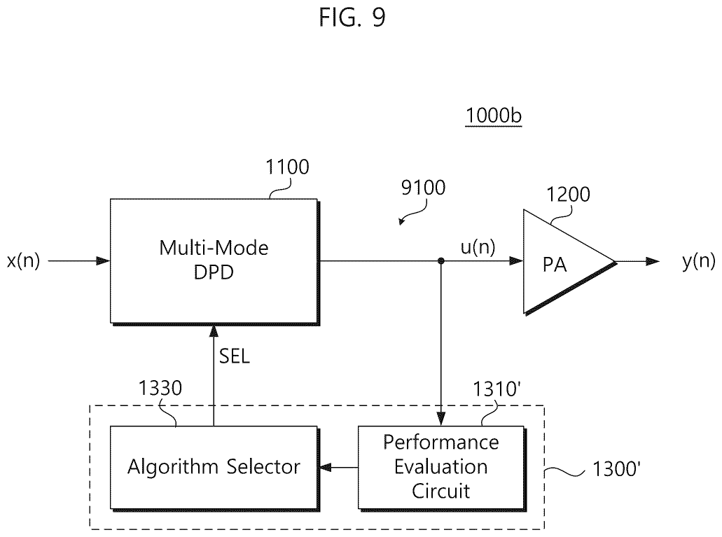

In one embodiment, the DPD mode selector 1300 analyzes an output signal y(n) of the power amplifier 1200 by analyzing a feedback signal FB representing the output signal y(n), obtained from the output signal y(n) through a coupler 1005. In another embodiment, illustrated by path 1007 (and described in relation to FIG. 9 below), the DPD mode selector 1300 analyzes the output signal u (n) of the DPD 1100. The DPD mode selector 1300 may select an operation mode of the multi-mode digital predistorter 1100 using the analysis results. The DPD mode selector 1300 operates according to the bias setting or transmission band of the power amplifier 1200 and/or various operating environments during a training process of the transmitting device 1000 or at the time of applying digital predistortion. To this end, the DPD mode selector 1300 receives the feedback signal FB, which may be a signal coupled from the amplifier output signal y(n) of the power amplifier 1200 (e.g., a lower amplitude version of y(n)). The DPD mode selector 1300 can detect gain, EVM, and/or ACLR according to bias setting or transmission band from the feedback signal FB. And the DPD mode selector 1300 can determine the DPD operation mode that provides optimal performance by referring to the detection result. Once the DPD operation mode is determined, the DPD mode selector 1300 transmits a selection signal SEL for selecting the DPD operation mode, to the DPD 1100. The selection signal SEL may include enable signals for activating or deactivating each operation mode.

According to the above-described configuration, the transmitting device 1000 of the present disclosure includes the DPD 1100, which may include a first kernel for memory polynomial MP mode operation and a second kernel that is selectively activated. The second kernel may perform the operation corresponding to the second term for processing the off-diagonal term of the Volterra series. Accordingly, the transmitting device 1000 can execute various modes of DPD operation while minimizing hardware costs.

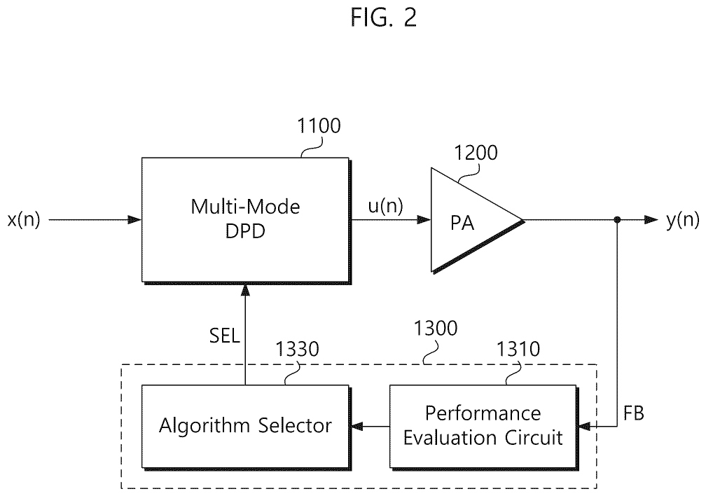

FIG. 2 is a block diagram illustrating a transmitting device 1000a, which is an embodiment of the transmitting device 1000 of FIG. 1. The transmitting device 1000a includes the DPD mode selector 1300, which may include a performance evaluation circuit 1310 and an algorithm selector 1330.

The multi-mode digital predistorter 1100 operates in one of a plurality of DPD operation modes according to the selection signal SEL. For example, the DPD 1100 operates in one of a memoryless ML polynomial mode, a memory polynomial (MP) mode, and a dynamic deviation reduction (DDR) mode. During training sequence or setup, the DPD 1100 can sequentially change the DPD operation mode. And performance in each DPD operation mode can be measured by the DPD mode selector 1300.

The power amplifier 1200 receives a predistortion signal u (n) output from the DPD 1100 to which digital predistortion DPD is applied according to the DPD operation mode selected by the DPD mode selector 1300. Then, the power amplifier 1200 may amplify the predistortion signal u (n) under preset bias setting conditions and output the amplified signal y(n). When the DPD 1100 is set to the DPD operation mode that can most effectively compensate for the nonlinearity or distortion characteristics of the power amplifier 1200, the linearity or efficiency of the amplification chain of the transmitting device 1000a (the amplification chain from the input of the DPD 1100 to the output of the power amplifier 1200) can be maximized.

The performance evaluation circuit 1310 receives a feedback signal FB (a coupled portion of the output signal y(n)) that feeds back a representation of the amplifier output signal y(n) of the power amplifier 1200. The performance evaluation circuit 1310 detects the performance of the multi-mode digital predistorter 1100 to select the DPD operation mode with the best performance in the channel environment, transmission band, and/or bias state of the power amplifier 1200. The performance evaluation circuit 1310 can detect at least one of the gain, EVM, and ACLR of the power amplifier 1200 for each bias setting of the power amplifier 1200 and the plurality of DPD operation modes in the transmission band.

For example, the performance evaluation circuit 1310 sets the DPD operation mode of the multi-mode digital predistorter 1100 to memoryless (ML) polynomial mode. Subsequently, the performance evaluation circuit 1310 may calculate at least one of the gain, EVM, and ACLR of the power amplifier 1200 under a memoryless (ML) polynomial mode. In addition, the performance evaluation circuit 1310 evaluates at least one of the gain, EVM, and ACLR of the power amplifier 1200 even in the memory polynomial (MP) mode and dynamic deviation reduction (DDR) mode of the multi-mode digital predistorter 1100. Here, the performance evaluation circuit 1310 may further change the bias setting and/or transmission band of the power amplifier 1200 to calculate the gain, EVM, and ACLR corresponding to the different bias setting/transmission band.

The algorithm selector 1330 selects the optimal DPD operation mode in the current transmission environment with reference to the performance of each DPD operation mode provided by the performance evaluation circuit 1310. For example, the algorithm selector 1330 selects the DPD operation mode using at least one of the gain, EVM, and ACLR of the power amplifier 1200 for each DPD operation mode. Here, the algorithm selector 1330 may determine the DPD operation mode that provides optimal performance among the memoryless (ML) polynomial mode, memory polynomial (MP) mode, and dynamic deviation reduction (DDR) mode. Then, the DPD operation mode of the DPD 1100 is set to operate in the determined DPD operation mode. The algorithm selector 1330 may output the selection signal SEL to activate the DPD operation mode of the DPD 1100 in the selected mode. The selection signal SEL may include a plurality of enable signals to set the DPD 1100 to one of the DPD operation modes.

Above, the configuration and operation of the DPD mode selector 1300 were briefly described. Although it has been described that the output signal of the power amplifier 1200 is used as the feedback signal FB to evaluate the performance of the DPD mode selector 1300, the inventive concept is not limited thereto. The signal used for performance evaluation may be the predistortion signal u (n) output from the multi-mode digital predistorter 1100, as described below for the embodiment of FIG. 9.

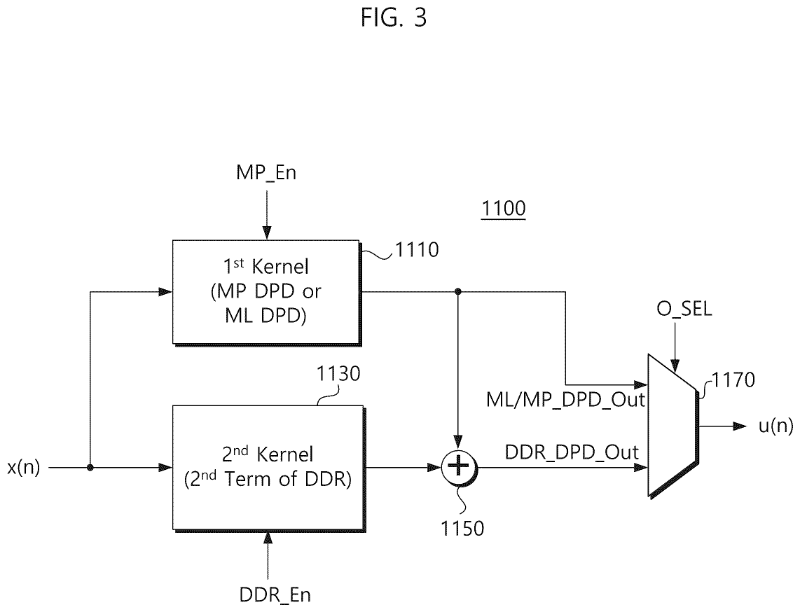

FIG. 3 is a block diagram showing an example structure of the multi-mode digital predistorter of FIG. 1 or FIG. 2. Referring to FIG. 3, the multi-mode digital predistorter (DPD) 1100 may include a first kernel processing circuit (“first kernel”) 1110, a second kernel processing circuit (“second kernel”) 1130, an adder 1150, and a selector 1170. Here, the enable signals (MP_En, DDR_En) and the output selection signal (O_SEL) are examples of the selection signal SEL in FIG. 1 or 2.

The first kernel 1110 performs a DPD operation in memory polynomial (MP) mode or memoryless (ML) polynomial mode for the baseband signal x(n) in response to the input memory polynomial mode enable signal MP_En. For example, when the memory polynomial mode enable signal MP_En is deactivated from the DPD mode selector 1300, the first kernel 1110 processes the baseband signal ‘x(n) in ML polynomial mode. On the other hand, when the memory polynomial mode enable signal MP_En from the DPD mode selector 1300 is activated, the first kernel 1110 processes the baseband signal x(n) in MP mode. The baseband signal x(n) processed in memoryless ML polynomial mode or memory polynomial MP mode may be provided as the first DPD output ML/MP_DPD_Out.

The digital predistortion DPD formula structure for variably executing the ML polynomial mode and the MP mode in the first kernel 1110 according to the memory polynomial mode enable signal MP_En can be expressed as Equation 1 (the ML polynomial case is described below in connection with Eqn. 2).

$${y}_{M P} ( n ) = {\sum }_{k = 0}^{K - 1} {\sum }_{m = 0}^{M - 1} {a}_{k , m} {\vert x ( n - m ) \vert}^{k} x ( n - m ) \qquad [ Equation 1 ]$$

Here, ‘a_{k,m} represents the polynomial coefficient, m represents the memory depth or length, M represents the maximum order of the memory length, and K represents the non-linear order for a truncated Volterra series.

When the memory polynomial mode enable signal MP_En is activated, the first kernel 1110 may perform a digital predistortion operation in the memory polynomial (MP) mode of Equation 1. On the other hand, if the memory polynomial mode enable signal MP_En is deactivated, the first kernel 1110 may perform a digital predistortion operation in the memoryless (ML) polynomial mode without considering previous inputs in Equation 1. In Equation 1, the digital predistortion operation in ML polynomial mode with memory depth ‘m’ set to ‘0’ to remove the influence of the previous input can be expressed as Equation 2 below.

$${y}_{M L} ( n ) = {\sum }_{k = 0}^{K - 1} {a}_{k , 0} {\vert x ( n ) \vert}^{k} x ( n ) \qquad [ Equation 2 ]$$

Here, a_{k,0} represents the polynomial coefficient in ML polynomial mode. In the polynomial of Equation 2, previous input signals are excluded and only the current baseband signal x(n) is considered.

In addition, when the multi-mode digital predistorter 1100 processes the baseband signal x(n) in dynamic deviation reduction (DDR) mode, the first kernel 1110 may provide the operation result of Equation 1 as the first term of the DDR operation. In other words, the first kernel 1110 processes the first term of the DDR operation in the DDR mode. In the DDR mode, the second term of the DDR operation may be processed in the second kernel 1130.

The second kernel 1130 processes the second term of the DDR operation in the DDR mode for the input baseband signal x(n). For example, when the DDR mode enable signal DDR_En is activated by the DPD mode selector 1300, the second kernel 1130 processes the second term of the DDR operation for the input baseband signal x(n). At this time, to process the first term of the DDR operation, the DPD mode selector 1300 may also activate the memory polynomial mode enable signal MP_En provided to the first kernel 1110.

The second term of the DDR operation for the baseband signal x(n) processed by the second kernel 1130 can be expressed as Equation 3 below.

$${y}_{DDR \_ 2} ( n ) = {\sum }_{k = 1}^{K - 1} {\sum }_{l = 1}^{L - 1} {b}_{k , l} {\vert x ( n ) \vert}^{2 ( k - 1 )} {x}^{2} ( n ) {x}^{*} ( n - l ) \qquad [ Equation 3 ]$$

Here, bk,l represents the polynomial coefficient of the off-diagonal term, and x*(n−1) represents the complex conjugate of x(n−1).

To execute the DDR mode, the DPD mode selector 1300 may activate the memory polynomial mode enable signal MP_En and the DDR mode enable signal DDR_En. Then, the first kernel 1110 performs the digital predistortion operation in the MP mode of Equation 1. And the second kernel 1130 will generate the second term of the DDR operation. Thus, the digital predistortion function in the DDR mode output by the adder 1150 can be expressed as Equation 4 below.

$${y}_{MP - DDR} ( n ) = {\sum }_{k = 0}^{K - 1} {\sum }_{m = 0}^{M - 1} {a}_{k , m} {\vert x ( n - m ) \vert}^{k} x ( n - m ) + {\sum }_{k = 1}^{K - 1} {\sum }_{l = 1}^{L - 1} {b}_{k , l} {\vert x ( n ) \vert}^{2 ( k - 1 )} {x}^{2} ( n ) {x}^{*} ( n - 1 ) \qquad [ Equation 4 ]$$

It is noted that the absolute value term |x(n−m)| of the first term in Equation 4 has a slight difference from a general DDR equation, but the effect on performance is minimal.

The selector 1170 outputs one of the first DPD output MP_DPD_Out from the first kernel 1110 and the second DPD output DDR_DPD_Out, which is the sum of the output of the first kernel 1110 and the output of the second kernel 1130 according to the output selection signal O_SEL. For example, the selector 1170 selects the first DPD output ML/MP_DPD_Out processed by the first kernel 1110 as the DPD output signal u (n) in ML polynomial mode or MP mode. On the other hand, in the DDR mode, the selector 1170 selects the second DPD output DDR_DPD_Out, which is the sum of the output of the first kernel 1110 and the output of the second kernel 1130, as the DPD output signal u (n). The output selection signal O_SEL is included as part of the selection signal SEL provided by the DPD mode selector 1300 described above.

In ML polynomial mode or MP mode, the second kernel 1130 is disabled. Thus, the DPD mode selector 1300 will deactivate the DDR mode enable signal DDR_En in ML polynomial mode or MP mode. Then, the second kernel 1130 is deactivated and will not perform any processing on the input baseband signal x(n). Accordingly, power consumption can be minimized by activating only the minimum hardware configurations required according to the DPD operation mode.

Above, a brief structure of the multi-mode digital predistorter 1100 has been described. The multi-mode digital predistorter 1100 may use the first kernel 1110 to perform digital predistortion processing in ML polynomial mode or MP mode. In addition, the multi-mode digital predistorter 1100 allows the first kernel 1110 to process the first term of the DDR operation in the DDR mode, and the second kernel 1130 to process the second term of the DDR operation. Ultimately, the multi-mode digital predistorter 1100 applies any one DPD operation mode among ML polynomial mode, MP mode, and DDR mode in various transmission environments.

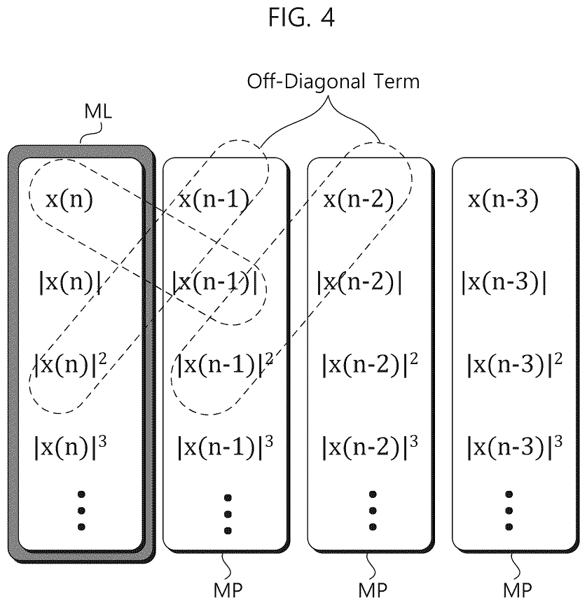

FIG. 4 is a diagram briefly showing example operation characteristics of a multi-mode digital predistorter of the present disclosure. Referring to FIG. 4, the input signal components of Equation 4 showing the operating characteristics of the multi-mode digital predistorter 1100 are arranged in a matrix form.

The first column is an arrangement of the current input baseband signal x(n) and the harmonic or modulation distortion signal components of x(n). For instance, the first column corresponds to inputs in memoryless (ML) polynomial mode where no delay is applied to the input baseband signal x(n). If the multi-mode digital predistorter (1100, see FIG. 3) operates in ML polynomial mode, the first kernel (1110, see FIG. 3) uses the input signal set in the first column {x(n)), |x(n)|, |x(n)|², . . . } to perform the predistortion operation of Equation 2.

The second column is arranged with x(n−1) delayed by the memory depth ‘1’ of the current input baseband signal x(n), and the harmonic or modulation distortion signal components of the input baseband signal x(n−1). And in the third column, the input baseband signal x(n−2) delayed by the memory depth ‘2’ of the current input baseband signal x(n), and the harmonic or modulation distortion signal components of x(n−2) are arranged. The fourth column contains the input baseband signal x(n−3) delayed by the memory depth ‘3’ of the current input baseband signal x(n), and the harmonic or modulation distortion signal components of x(n−3). When the multi-mode digital predistorter 1100 is set to memory polynomial (MP) mode, the first kernel 1110 may perform the predistortion operation of Equation 1 using all input signal sets of each column.

Additionally, off-diagonal terms define the correlation between input signals of different memory depths. For example, as illustrated in FIG. 4, the memoryless polynomial term |x(n)|² used in Equation 3 and the input baseband signal x(n−1) delayed by the memory depth ‘1’ are off-diagonal terms used for the second term of the DDR operation (the conjugate x*(n−1) of x(n−1) is used in Equations 3 and 4). In the DDR mode, the first kernel 1110 is used to process the first term of the DDR operation, and the second kernel 1130 is used to process the second term of the DDR operation.

As a result, the multi-mode digital predistorter 1100 can apply any one of the ML polynomial mode, the MP mode, or the DDR mode in various transmission environments. In certain environments, there may be no difference in performance between DDR mode, which consumes relatively high power, and MP mode or ML polynomial mode. In this case, low-power performance can be improved in a mobile environment by activating MP mode or ML polynomial mode rather than DDR mode.

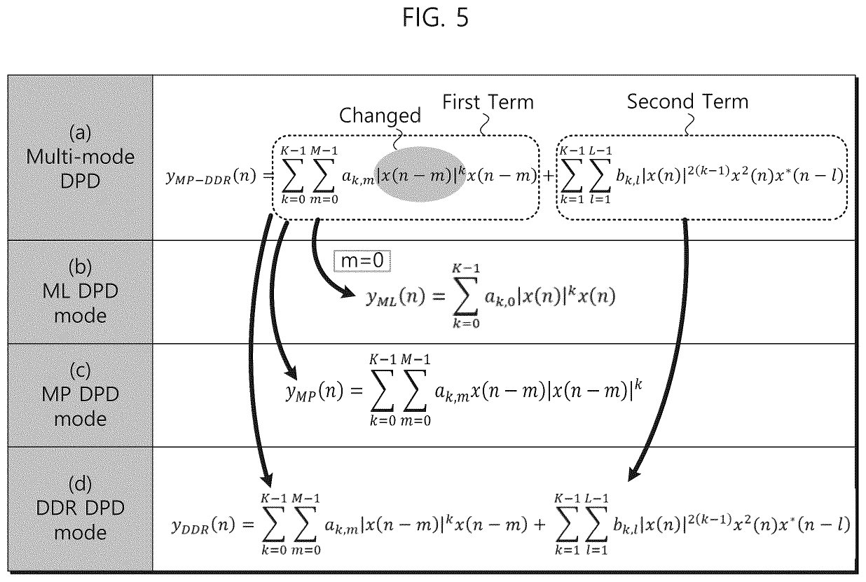

FIG. 5 is a table showing the types of processing operations for each DPD operation mode of a multi-mode digital predistorter of the present disclosure. Referring to FIG. 5, the multi-mode digital predistorter (1100, see FIG. 3) performs digital predistortion operations in memoryless (ML) polynomial mode, memory polynomial (MP) mode, and dynamic deviation reduction (DDR) mode.

The multi-mode digital predistorter 1100 can implement various DPD operation modes using a first kernel 1110, a second kernel 1130, an adder 1150, and a selector 1170. To provide these various DPD operation modes, the first kernel 1110, the second kernel 1130, and the adder 1150 operate the first term and the second term of the Equation in (a) of FIG. 5 individually or jointly. The part indicated as ‘Changed’ in the first term corresponds to a part that differs from a general dynamic deviation reduction (DDR) DPD calculation formula. However, even if the predistortion is calculated according to the DPD operation mode of the present disclosure, there is little difference in performance from the general DDR DPD equation.

The equation in (b) shows the operation characteristics of the first kernel 1110 when the memory polynomial mode enable signal MP_En and the DDR mode enable signal DDR_En are deactivated. In other words, it shows the operation when the first kernel 1110 operates in ML polynomial mode. As the DDR mode enable signal DDR_En is deactivated, the second kernel 1130 is deactivated. And in order to execute the ML polynomial mode, the first kernel 1110 applies the memory depth m to ‘0’, and the operation of the ML polynomial mode in the illustrated form can be performed.

The equation in (c) shows the operation calculated by the first kernel 1110 in MP mode. That is, it shows the operation characteristics of the first kernel 1110 when the memory polynomial mode enable signal MP_En is activated and the DDR mode enable signal DDR_En is deactivated. As the DDR mode enable signal DDR_En is deactivated, the second kernel 1130 is deactivated. And to execute the memory polynomial MP mode, the first kernel 1110 will calculate the Volterra series corresponding to the first term. The DPD value output from the first kernel 1110 will be provided to the selector 1170 without going through the adder 1150 (see FIG. 3).

The equation in (d) shows the operation in dynamic deviation reduction (DDR) mode. When the memory polynomial mode enable signal MP_En and the DDR mode enable signal DDR_En are activated, each of the first kernel 1110 and the second kernel 1130 executes a DDR mode operation. Upon activation of the memory polynomial mode enable signal MP_En, the first kernel 1110 will calculate the Volterra series corresponding to the first term. And as the DDR mode enable signal DDR_En is activated, the second kernel 1130 processes the second term of the DDR operation for the input baseband signal x(n). And the outputs of the first kernel 1110 and the second kernel 1130 may be summed and output in the adder 1150.

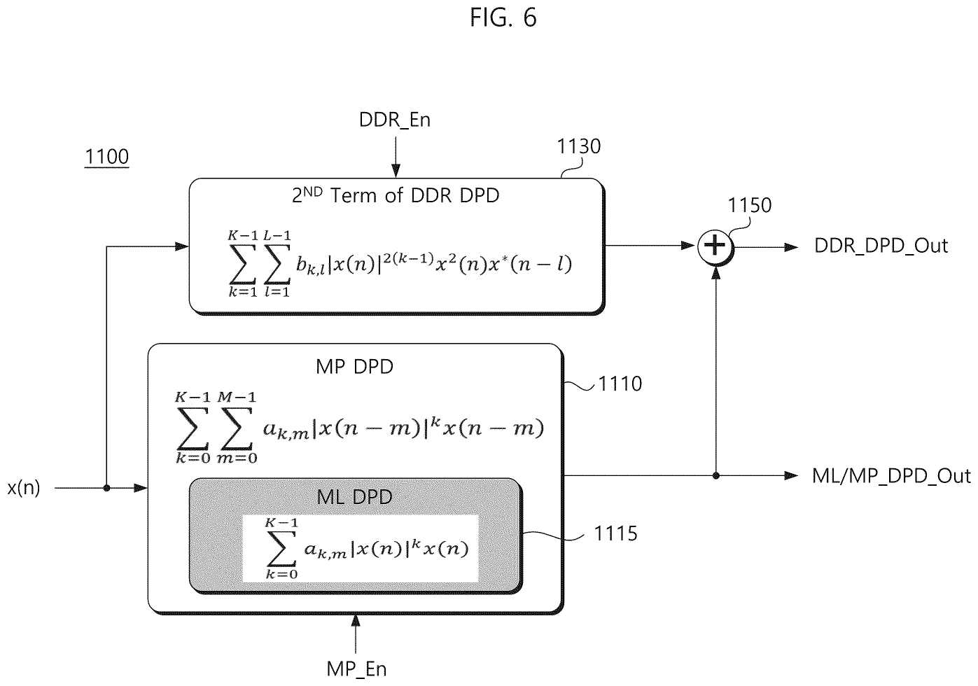

FIG. 6 is a block diagram showing the operation method of the first kernel and the second kernel of the present disclosure. Referring to FIG. 6, the first kernel 1110 performs a memory polynomial DPD operation or a memoryless DPD operation on the input baseband signal x(n). And the second kernel 1130 performs the second term of the DDR operation.

When the MP mode enable signal MP_En provided from the DPD mode selector 1300 is deactivated, the first kernel 1110 processes the input baseband signal x(n) in ML polynomial mode. As the DDR mode enable signal DDR_En is deactivated, the second kernel 1130 is deactivated. And when the first kernel 1110 sets the memory depth m to ‘0’ to execute the memoryless ML polynomial mode, the memory polynomial MP mode is reduced to operation 1115 of the memoryless ML polynomial mode in the form shown. The DPD value of the memoryless ML polynomial mode output from the first kernel 1110 will be output as a result value ML_DPD_Out without going through the adder 1150.

When the MP mode enable signal MP_En is activated, the first kernel 1110 will calculate the Volterra series corresponding to the first term expressed in Equation 1. The DPD value of the memory polynomial mode output from the first kernel 1110 will be output as a result value MP_DPD_Out without going through the adder 1150.

When the MP mode enable signal MP_En and the DDR mode enable signal DDR_En are activated, the first kernel 1110 and the second kernel 1130 perform respective operations. Upon activation of the MP mode enable signal MP_En, the first kernel 1110 will calculate the Volterra series corresponding to the first term. And as the DDR mode enable signal DDR_En is activated, the second kernel 1130 processes the second term of the dynamic deviation reduction DDR operation for the input baseband signal ‘x(n)’. And the outputs of the first kernel 1110 and the second kernel 1130 will be summed in the adder 1150 to output a result value DDR_DPD_Out in the dynamic deviation reduction DDR mode.

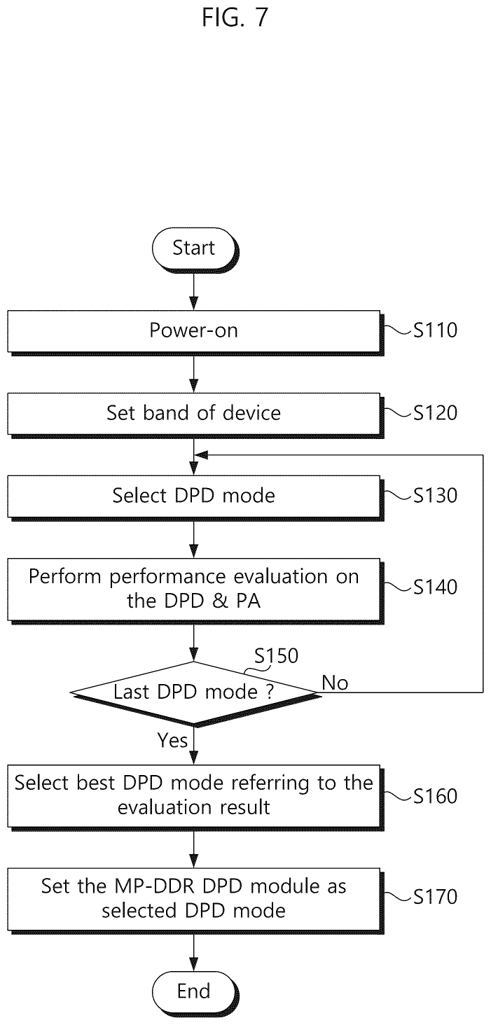

FIG. 7 is a flow chart showing the setting procedure of the multi-mode digital predistorter performed during the training operation of a transmitting device of the present disclosure. Referring to FIG. 7, a DPD mode with optimal performance may be selected from a plurality of DPD modes according to the transmission band of the transmitting device 1000. Here, the training procedure of the multi-mode digital predistorter 1100 performed when the transmitting device 1000 is booted will be described as an example. However, it will be appreciated that reset or training of the multi-mode digital predistorter 1100 may be performed under various conditions.

In operation S110, power may be provided to the transmitting device 1000 through initialization or power provision. In this case, the initialization sequence will be applied as the driving power of the transmitting device 1000 is supplied.

In operation S120, the band of the transmitting device 1000 is set. For example, in the case of the power amplifier 1200 covering multiple bands, impedance matching or bias may be set to optimize the target transmission frequency band.

In operation S130, a digital predistortion DPD mode is selected to compensate for the non-linearity or distortion characteristics of the power amplifier 1200 in the set band. For example, the DPD mode selector 1300 can select the multi-mode digital predistorter 1100 in any one of ML polynomial mode, MP mode, and DDR mode.

In operation S140, the DPD mode selector 1300 performs performance evaluation of the power amplifier 1200 in the selected digital predistortion DPD mode. For example, the performance evaluation circuit 1310 (see FIG. 2) evaluates at least one of the gain, the error vector magnitude EVM, and adjacent channel leakage ratios ACLR of the power amplifier 1200 from the feedback signal FB that feeds back the output of the power amplifier 1200.

In operation S150, the DPD mode selector 1300 determines whether the digital predistortion DPD mode set in operation S130 is the last mode selected for performance evaluation. For example, the DPD mode selector 1300 checks whether the mode set in operation S130 is the last mode among a plurality of digital predistortion DPD modes. If the digital predistortion DPD mode set in operation S130 is the last mode for evaluation (‘Yes’ direction), the procedure moves to operation S160. On the other hand, if the digital predistortion DPD mode set in operation S130 is not the last mode for evaluation (‘No’ direction), the procedure returns to operation S130 and selects another digital predistortion DPD mode.

In operation S160, the DPD mode selector 1300 selects one of the evaluated memoryless ML polynomial mode, memory polynomial MP mode, and dynamic deviation reduction DDR mode that provides optimal performance. The DPD mode selector 1300 compares the gain, EVM, and ACLR for each case to select a DPD mode that shows optimal performance in the selected band.

In operation S170, the DPD mode selector 1300 will set the multi-mode digital predistorter 1100 to the selected DPD mode.

In the above, the DPD mode selection procedure of the multi-mode digital predistorter 1100 performed during training of the transmitter 1000 has been briefly described. According to the present disclosure, the optimal DPD mode can be selected according to the transmission band of the power amplifier 1200 or the transmission device 1000.

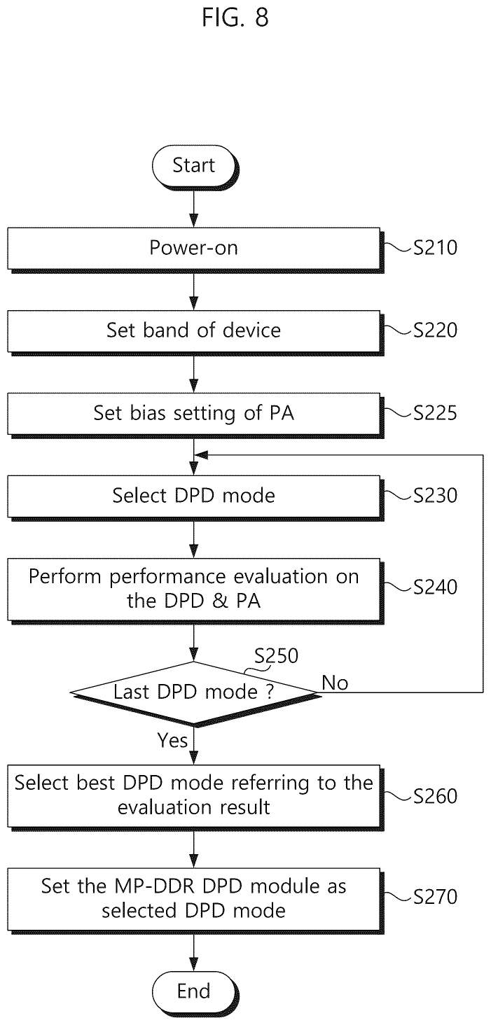

FIG. 8 is a flowchart showing a setting procedure for a multi-mode digital predistorter performed during a training operation of a transmitting device according to another embodiment of the present disclosure. Referring to FIG. 8, a DPD mode with optimal performance can be selected from a plurality of DPD modes according to the bias setting of the transmitting device 1000.

In operation S210, power may be provided to the transmitting device 1000 through initialization or power provision. In this case, the initialization sequence will be applied as the driving power of the transmitting device 1000 is supplied.

In operation S220, the band of the transmitting device 1000 is set. For example, in the case of the power amplifier 1200 covering multiple bands, impedance matching or bias may be set to optimize the target transmission frequency band.

In operation S225, a bias condition of the power amplifier 1200 is set. For example, the voltage or current bias of the power amplifier 1200 may be adjusted depending on the transmission environment.

In operation S230, a digital predistortion DPD mode is selected to compensate for the non-linearity or distortion characteristics of the power amplifier 1200 in the set band. For example, the DPD mode selector 1300 can select the multi-mode digital predistorter 1100 in any one of ML polynomial mode, MP mode, and DDR mode.

In operation S240, the DPD mode selector 1300 performs performance evaluation of the power amplifier 1200 in the selected digital predistortion DPD mode. For example, the performance evaluation circuit 1310 calculates at least one of the gain, the EVM, and ACLR of the power amplifier 1200 from the feedback signal FB that feeds back a coupled output of the power amplifier 1200.

In operation S250, the DPD mode selector 1300 determines whether the digital predistortion DPD mode set in operation S230 is the last mode selected for performance evaluation. For example, the DPD mode selector 1300 checks whether the mode set in operation S230 is the last mode among a plurality of digital predistortion DPD modes. If the digital predistortion DPD mode set in operation S230 is the last mode for evaluation (‘Yes’ direction), the procedure moves to operation S260. On the other hand, if the digital predistortion DPD mode set in operation S230 is not the last mode for evaluation (‘No’ direction), the procedure will return to operation S230 and select another digital predistortion DPD mode.

In operation S260, the DPD mode selector 1300 selects one of the evaluated ML polynomial mode, MP mode, and DDR mode that provides optimal performance. The DPD mode selector 1300 compares the gain, EVM, and ACLR for each case to select a DPD mode that shows optimal performance in the selected band.

In operation S270, the DPD mode selector 1300 will set the multi-mode digital predistorter 1100 to the selected DPD mode.

In the above, the digital predistortion mode selection procedure of the multi-mode digital predistorter 1100 performed during training of the transmitter 1000 of the present disclosure has been briefly described. According to the present disclosure, the optimal digital predistortion DPD mode can be selected according to the bias setting of the power amplifier 1200.

FIG. 9 is a block diagram illustrating a transmitting device 1000b, which is another embodiment of the transmitting device 1000 of FIG. 1. The transmitting device 1000b includes DPD processing circuitry 9100 which evaluates the digital predistortion performance using the predistortion signal u (n) output from the DPD 1100 rather than the output of the power amplifier 1200. The DPD processing circuitry 9100 may include a DPD mode selector 1300′ and the multi-mode digital predistorter 1100.

The multi-mode digital predistorter 1100 (“DPD 1100”) operates in one of a plurality of DPD operation modes according to the selection signal SEL. The DPD 1100 operates in any one of memoryless (ML) polynomial mode, memory polynomial (MP) mode, and dynamic variation reduction (DDR) mode. When training or setting the transmitting device 1000b, the DPD processing circuitry 9100 can sequentially change the DPD operation mode. And, performance in each DPD operation mode can be measured by the DPD mode selector 1300′.

The performance evaluation circuit 1310′ receives the predistortion signal u (n) output by the DPD 1100. The performance evaluation circuit 1310′ analyzes the output signal u(n) to select a DPD operation mode with the best performance in the current transmission band of the transmitter 1000 and/or bias setting of the power amplifier 1200. The performance evaluation circuit 1310′ determines at least one of the gain, error vector magnitude EVM, and adjacent channel leakage ratio ACLR of the power amplifier 1200 for each of the plurality of DPD operation modes in the transmission band and bandwidth of the current transmission device 1000b. Here, the performance evaluation circuit 1310′ may further change the bias setting and/or the transmission band of the power amplifier 1200 to determine gain, the EVM, and ACLR corresponding to another frequency band/bias setting. Because the output signal u(n) does not include the performance characteristics of the power amplifier 1200, the gain, EVM and/or ACLR may be calculated by the performance evaluation circuit 1310′ using estimated or previously measured performance characteristics of the power amplifier 1200.

The algorithm selector 1330 selects the optimal DPD operation mode with reference to the performance of each DPD operation mode provided by the performance evaluation circuit 1310′. For example, the algorithm selector 1330 uses the calculated gain, the EVM, and/or the ACLR of the output signal y(n) of the power amplifier 1200 for each DPD operation mode to select one of the ML polynomial mode, MP mode, and DDR mode. Then, the operation mode of the multi-mode digital predistorter 1100 is determined to operate in the determined DPD operation mode. The algorithm selector 1330 outputs a selection signal SEL to activate the determined DPD operation mode of the multi-mode digital predistorter 1100.

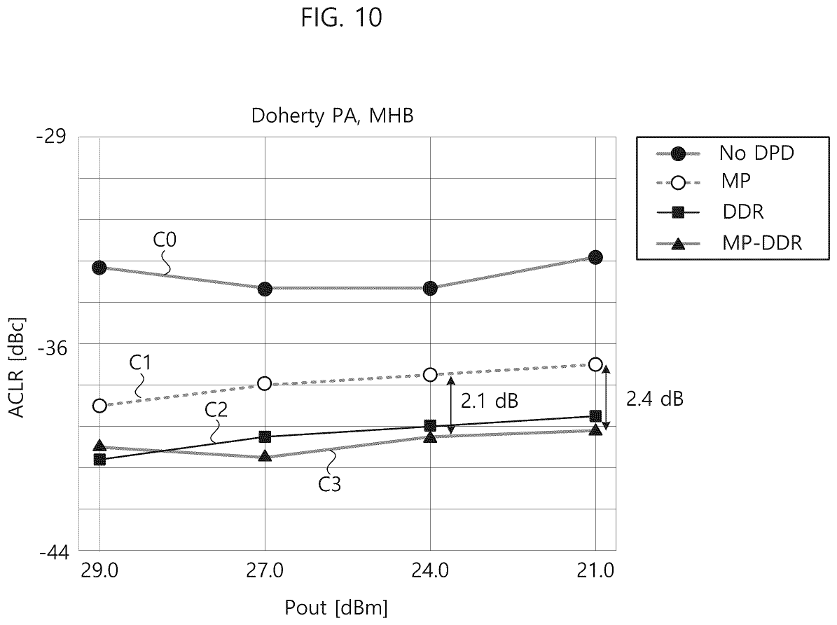

FIG. 10 shows example adjacent channel leakage ratio ACLR performance in the mid-high band MHB of a multi-mode digital predistorter of the present disclosure. Referring to FIG. 10, the multi-mode digital predistorter 1100 of the present disclosure provides a performance improvement of more than 2 dB through a digital predistortion operation for the power amplifier 1200 implemented with a Doherty power amplifier.

Curve ‘C0’ shows the adjacent channel leakage ratio ACLR of the Doherty power amplifier when no digital predistortion is applied in the mid to high band MHB with a center frequency of 2593 MHz. In this case, the adjacent channel leakage ratio ACLR is approximately −34 dBc depending on the change in the output of the power amplifier 1200.

Curve ‘C1’ shows the adjacent channel leakage ratio ACLR of the Doherty power amplifier when only digital predistortion in memory polynomial MP mode is applied in the mid to high band MHB with a center frequency of 2593 MHz. In this case, the adjacent channel leakage ratio ACLR is approximately −38 dBc depending on the change in the output of the power amplifier 1200. In other words, a relatively large performance improvement is apparent as compared to when digital predistortion was not applied.

Curve ‘C2’ shows the adjacent channel leakage ratio ACLR of the Doherty power amplifier when only digital predistortion in dynamic deviation reduction DDR mode is applied in the mid-to-high band MHB with a center frequency of 2593 MHz. In this case, the adjacent channel leakage ratio ACLR is approximately −39.5 dBc depending on the change in the output of the power amplifier 1200. It can be seen that when digital predistortion in dynamic deviation reduction DDR mode is applied, a relatively large performance improvement is possible compared to when only memory polynomial MP mode is applied.

Curve ‘C3’ shows the adjacent channel leakage ratio ACLR of the Doherty power amplifier when using the multi-mode digital predistorter 1100 of the present disclosure in the mid to high band MHB with a center frequency of 2593 MHz. In this case, although there is a difference in degree depending on the change in the output of the power amplifier 1200, the adjacent channel leakage ratio ACLR is approximately −40.5 dBc. In other words, it can be seen that when the DPD operation mode can be varied in the mid-to-high band MHB conditions, performance improvement of more than 2 dB is possible compared to when only the memory polynomial MP mode is used.

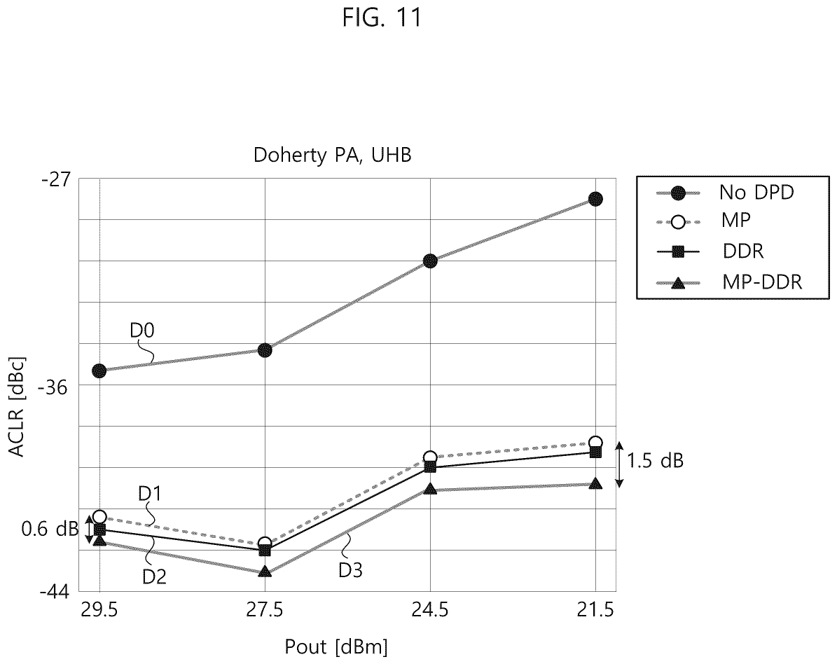

FIG. 11 shows example adjacent channel leakage ratio ACLR performance of a multi-mode digital predistorter of the present invention in the ultra-high band UHB. Referring to FIG. 11, the multi-mode digital predistorter 1100 of the present invention provides a performance improvement of more than 2 dB through a digital predistortion operation for the power amplifier 1200 implemented with a Doherty power amplifier.

Curve ‘D0’ shows the adjacent channel leakage ratio ACLR of the Doherty power amplifier when no digital predistortion is applied in the ultra-high band UHB with a center frequency of 3550 MHz. In this case, adjacent channel leakage ratio ACLR performance of −36 dBm to −28 dBm is shown depending on the change in output Pout of the power amplifier 1200.

Curve ‘D1’ shows the adjacent channel leakage ratio ACLR of the Doherty power amplifier when only digital predistortion in memory polynomial MP mode is applied in the ultra-high band UHB with a center frequency of 3550 MHz. Curve ‘D2’ shows the adjacent channel leakage ratio ACLR of the Doherty power amplifier when only digital predistortion in dynamic deviation reduction DDR mode is applied in the ultra-high band UHB with a center frequency of 3550 MHz. According to curves ‘D1’ and ‘D2’, it can be seen that performance is clearly improved as compared to when digital predistortion is not applied according to the change in the output of the power amplifier 1200.

Curve ‘D3’ shows example adjacent channel leakage ratio ACLR of the Doherty power amplifier when using the multi-mode digital predistorter 1100 of the present disclosure in the ultra-high band UHB with a center frequency of 3550 MHz. In this case, although there is a difference in degree depending on the change in the output of the power amplifier 1200, it can be seen that performance improvement of about 0.6 dB to 1.5 dB is possible compared to curve ‘D1’ where only the memory polynomial MP mode is applied. Referring to the above performance evaluation results, when using the multi-mode digital predistorter 1100 of the present disclosure, it is possible to provide higher performance than when using only the memory polynomial MP mode or dynamic deviation reduction DDR mode.

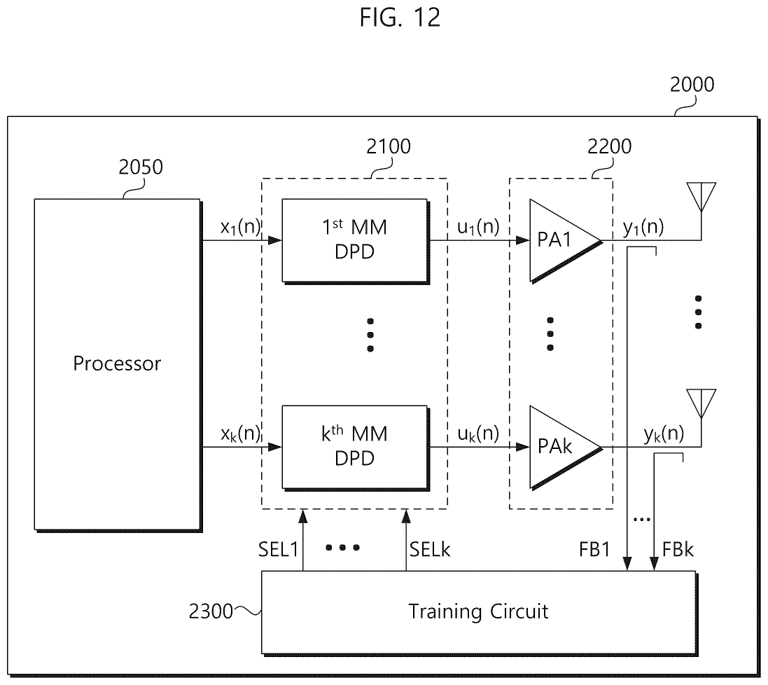

FIG. 12 is a block diagram showing a mobile device transmitting a transmission signal in multiple bands according to another embodiment of the present disclosure. Referring to FIG. 12, the mobile device 2000 may include a processor 2050, a multi-mode digital predistorter circuit 2100, a power amplifier circuit 2200, and a training circuit 2300.

Processor 2050 generates a baseband signal to be transmitted. For example, the processor 2050 may generate baseband signals x₁(n) to xₖ(n) to provide to the multi-mode digital predistorter circuit 2100.

The multi-mode digital predistorter circuit 2100 detects nonlinearity of the power amplifier circuit 2200 and applies predistortion compensation to each of the baseband signal x₁(n) to the baseband signal xₖ(n). The multi-mode digital predistorter circuit 2100 includes a first multi-mode digital predistorter 1st MM DPD to a kth multi-mode digital predistorter kth MM DPD for applying predistortion operations for each band. The first multi-mode digital predistorter 1st MM DPD performs digital predistortion processing to compensate for the nonlinearity of the first power amplifier PA1. To this end, the first multi-mode digital predistorter 1st MM DPD performs a digital predistortion operation on the baseband signal x₁(n).

In particular, the first multi-mode digital predistorter 1st MM DPD of the present disclosure selects a digital predistortion DPD mode optimized for the transmission band and bias setting of the first power amplifier PA1. For instance, the first multi-mode digital predistorter 1st MM DPD can apply digital predistortion operation to the baseband signal x₁(n) in any one of the memoryless ML polynomial mode, memory polynomial MP mode, and dynamic deviation reduction DDR mode. Selection of the digital predistortion DPD mode may be performed at booting or when necessary under the control of the training circuit 2300. Likewise, the second multi-mode digital predistorter 2nd MM DPD to the kth multi-mode digital predistorter kth MM DPD also can select a digital predistortion DPD mode optimized for bias setting and/or the transmission band of each of the corresponding power amplifiers (PA2 to PAK). Each of the above-described digital predistorters 1st MM DPD to kth MM DPD may include the structure of FIG. 3 described above. (Alternatively, they each include the structure of FIG. 9 described above, in which the output signals u₁(n) to uₖ(n) are analyzed by the training circuit 2300 instead of the output signals y₁(n) to yₖ(n)).

The power amplifier circuit 2200 may include a plurality of power amplifiers PA1 to PAK for power amplification for each band. Each of the plurality of power amplifiers PA1 to PAK amplifies a respective one of the predistortion signals u₁(n) to uₖ(n) transmitted from the digital predistorters 1^{st} MM DPD to k^{th} MM DPD and provides respective outputs as output signals y₁(n) to yₖ(n). Each of the plurality of power amplifiers PA1 to PAK may be a high-efficiency Doherty power amplifier. Alternatively, each of the power amplifiers PA1 to PAK is any suitable type of power amplifier that requires pre-compensation for non-linearity or distortion.

The training circuit 2300 may select the DPD mode of operation of multi-mode digital predistorter circuit 2100 using the output of each of the plurality of power amplifiers PA1 to PAK or the output of the multi-mode digital predistorter circuit 2100. The training circuit 2300 may select a DPD operation mode according to the bias settings, bands, and/or various operations of a plurality of power amplifiers (PA1 to PAK) during the training process of the mobile device 2000 or when digital predistortion DPD is applied. To this end, the training circuit 2300 receives feedback signals FB1 to FBk obtained by feeding back output signals y₁(n) to yₖ(n) of each of the plurality of power amplifiers PA1 to PAK. And the training circuit 2300 analyzes uses the feedback signals FB1 to FBk to determine the bias setting, gain, EVM, and/or ACLR according to the band of each of the plurality of power amplifiers PA1 to PAK. Using the analysis results, the training circuit 2300 may determine a DPD operation mode that can provide optimal performance for each of the plurality of power amplifiers PA1 to PAK. Once the DPD operation mode that can provide optimal performance for each of the plurality of power amplifiers PA1 to PAK is determined, the training circuit 2300 may set each of the digital predistorters 1^{st} MM DPD to k^{th} MM DPD to the selected DPD mode.

According to the above-described configuration, the mobile device 2000 of the present disclosure can compensate for the nonlinearity of each of the plurality of power amplifiers PA1 to PAK according to various bias settings or bands. Here, each of the digital predistorters 1^{st} MM DPD to k^{th} MM DPD in the multi-mode digital predistorter circuit 2100 includes a first kernel for operation of the memory polynomial MP mode and a second kernel selectively activated. The second kernel may perform an operation corresponding to the second term for processing the off-diagonal term of the Volterra series. Accordingly, the mobile device 2000 can execute various modes of DPD operation while minimizing hardware costs.

Exemplary embodiments of the inventive concept have been described herein with reference to signal arrows, block diagrams and algorithmic expressions. Each block of the block diagrams and combinations of blocks in the block diagrams, and operations according to the algorithmic expressions can be implemented by hardware (e.g., processing circuitry of DPD mode selector 1300 or multi-mode DPD 1100 in cooperation with a memory within the transmitting device 1000 that stores computer program instructions. Such computer program instructions may be stored in a non-transitory computer readable medium that can direct a computer, other programmable data processing apparatus, or other devices to function in a particular manner, such that the instructions stored in the computer readable medium produce an article of manufacture including instructions which implement the function/act specified in the block diagram. The term “processor” or “processing circuitry” as used herein is intended to include any processing device, such as, for example, one that includes a central processing unit (CPU) and/or other processing circuitry (e.g., digital signal processor (DSP), microprocessor, an application specific gate array (ASIC), a field programmable gate array (FPGA), etc.). Moreover, a “processor” includes computational hardware and may refer to a multi-core processor that contains multiple processing cores in a computing device. Various elements associated with a processing device may be shared by other processing devices.

The above are specific embodiments for carrying out the inventive concept. While the inventive concept has been particularly shown and described with reference to embodiments thereof, it will be understood that various changes in form and details may be made therein without departing from the spirit and scope of the following claims and their equivalents.

What is claimed is:

1. A transmitting device comprising:
a multi-mode digital predistorter circuit configured to pre-compensate an input baseband signal in one of a plurality of digital predistortion modes according to a selection signal;
a power amplifier configured to amplify the pre-compensated baseband signal and output the amplified baseband signal as an output signal of an allocated band; and
a digital predistortion mode selector circuit configured to determine the one of the plurality of digital predistortion modes corresponding to the allocated band using a feedback signal obtained from the output signal, and set the multi-mode digital predistorter circuit to the one of the determined modes.

2. The transmitting device of claim 1, wherein the plurality of digital predistortion modes include a memoryless polynomial mode, a memory polynomial mode, and a dynamic deviation reduction mode.

3. The transmitting device of claim 2, wherein the multi-mode digital predistorter circuit comprises:
first kernel processing circuitry configured to process the input baseband signal in one of the memoryless polynomial mode and the memory polynomial mode in response to a first enable signal;
second kernel processing circuitry configured to perform some operation of the dynamic deviation reduction mode on the input baseband signal in response to a second enable signal; and
an adder configured to add a first term signal output from the first kernel processing circuitry and a second term signal output from the second kernel processing circuitry to provide the pre-compensated baseband signal in the dynamic deviation reduction mode.

4. The transmitting device of claim 3, wherein in the memoryless polynomial mode, the first enable signal and the second enable signal are deactivated,
wherein in the memory polynomial mode, the first enable signal is activated and the second enable signal is deactivated, and
wherein in the dynamic deviation reduction mode, the first enable signal and the second enable signal are activated.

5. The transmitting device of claim 4, wherein the multi-mode digital predistorter circuit includes a selector configured to select one of the output of the first kernel processing circuitry and the output of the adder according to the plurality of digital predistortion modes to provide the pre-compensated baseband signal.

6. The transmitting device of claim 5, wherein the selector selects the output of the first kernel processing circuitry in the memoryless polynomial mode and the memory polynomial mode, and selects the output of the adder in the dynamic deviation reduction mode.

7. The transmitting device of claim 3, wherein the first term signal corresponds to
$${\sum }_{k = 0}^{K - 1} {\sum }_{m = 0}^{M - 1} {α}_{k , m} {\vert x ( n - m ) \vert}^{k} x ( n - m ) ,$$
where a_{k,m} represents a polynomial coefficient of the diagonal term, M is a maximum order of memory length, K is a non-linear order, and m is a memory depth), and the second term signal corresponds to
$${\sum }_{k = 1}^{K - 1} {\sum }_{l = 1}^{L - 1} {b}_{k , l} {\vert x ( n ) \vert}^{2 ( k - 1 )} {x}^{2} ( n ) {x}^{*} ( n - 1 ) ,$$
where b_{k,l} is a polynomial coefficient of an off-diagonal term, and x*(n−1) is a complex conjugate of x(n−1)).

8. The transmitting device of claim 7, wherein the memory depth ‘m’ is set to ‘0’ in the memoryless polynomial mode.

9. The transmitting device of claim 1, wherein the digital predistortion mode selector circuit comprises:
a performance evaluation circuit configured to evaluate performance of the multi-mode digital predistorter circuit by analyzing the feedback signal; and
an algorithm selector configured to determine the one of the plurality of digital predistortion modes according to the performance evaluation result and set an operation mode of the multi-mode digital predistorter circuit to the one of the plurality of digital predistortion modes.

10. The transmitting device of claim 9, wherein the digital predistortion mode selector circuit determines the operation mode while varying the bias setting or a frequency band of the power amplifier.

11. A predistortion method of a digital predistorter to compensate for nonlinearity of a power amplifier:
evaluating the performance of the digital predistorter in each of a plurality of digital predistortion modes;
selecting one of the plurality of digital predistortion modes based on the evaluated performance; and
setting the digital predistorter to any one of the selected modes,
wherein the digital predistorter comprises:
first kernel processing circuitry configured to process an input baseband signal in one of a memoryless polynomial mode and a memory polynomial mode in response to a first enable signal;
second kernel processing circuitry configured to perform an operation of a dynamic deviation reduction mode on the input baseband signal in response to a second enable signal; and
an adder configured to add a first term signal output from the first kernel processing circuitry and a second term signal output from the second kernel processing circuitry to provide a pre-compensated baseband signal in the dynamic deviation reduction mode.

12. The method of claim 11, further comprising:
adjusting at least one of a transmission band or bias setting of the power amplifier and again evaluating the performance of the digital predistorter in each of the plurality of digital predistortion modes.

13. The method of claim 11, wherein the performance of the digital predistorter includes at least one of a gain of the power amplifier, an adjacent channel leakage ratio (ACLR), and an error vector magnitude (EVM).

14. The method of claim 11, wherein the plurality of digital predistortion modes include a memoryless polynomial mode, a memory polynomial mode, and a dynamic deviation reduction mode.

15. The method of claim 14, wherein the first term signal corresponds to
$${\sum }_{k = 0}^{K - 1} {\sum }_{m = 0}^{M - 1} {α}_{k , m} {\vert x ( n - m ) \vert}^{k} x ( n - m ) ,$$
where ‘a_{k,m}’ represents a polynomial coefficient of a diagonal term, M is a maximum order of a memory length, K is a non-linear order, and m is a memory depth, and the second term signal corresponds to
$${\sum }_{k = 1}^{K - 1} {\sum }_{l = 1}^{L - 1} {b}_{k , l} {\vert x ( n ) \vert}^{2 ( k - 1 )} {x}^{2} ( n ) {x}^{*} ( n - 1 ) ,$$
where b_{k,l} is a polynomial coefficient of an off-diagonal term, and x*(n−1) is a complex conjugate of x(n−1).

16. The method of claim 15, wherein in the memoryless polynomial mode, the first enable signal and the second enable signal are deactivated,
wherein in the memory polynomial mode, the first enable signal is activated and the second enable signal is deactivated, and
wherein in the dynamic deviation reduction mode, the first enable signal and the second enable signal are activated.

17. The method of claim 16, wherein the memory depth m is set to ‘0’ in the memoryless polynomial mode.

18. A digital predistorter to pre-compensate for nonlinearity in a power amplifier, comprising:
first kernel processing circuitry configured to process an input baseband signal in one of a memoryless polynomial mode and a memory polynomial mode in response to a first enable signal;
second kernel processing circuitry configured to perform an operation in a dynamic deviation reduction mode on the input baseband signal in response to a second enable signal;
an adder configured to add a first term signal output from the first kernel processing circuitry and a second term signal output from the second kernel processing circuitry to provide a pre-compensated baseband signal in the dynamic deviation reduction mode; and
a selector configured to select one of the first term signal and an output of the adder in response to a selection signal,
wherein the first term signal corresponds to
$${\sum }_{k = 0}^{K - 1} {\sum }_{m = 0}^{M - 1} {α}_{k , m} {\vert x ( n - m ) \vert}^{k} x ( n - m ) ,$$
where a_{k,m} represents a polynomial coefficient of a diagonal term, M is a maximum order of memory length, K is a non-linear order, and m is a memory depth, and the second term signal corresponds to
$${\sum }_{k = 1}^{K - 1} {\sum }_{l = 1}^{L - 1} {b}_{k , l} {\vert x ( n ) \vert}^{2 ( k - 1 )} {x}^{2} ( n ) {x}^{*} ( n - 1 ) ,$$
where b_{k,l} is a polynomial coefficient of an off-diagonal term, and x*(n−1) is a complex conjugate of x(n−1).

19. The digital predistorter of claim 18, further comprising:
a digital predistortion mode selector circuit configured to determine one of a plurality of digital predistortion modes corresponding to the allocated band using a fed back output signal of the power amplifier, and set the digital predistorter to the one of the determined modes.

20. The digital predistorter of claim 18, wherein in the memoryless polynomial mode, the first enable signal and the second enable signal are deactivated and the memory depth m is set to ‘0’,
wherein in the memory polynomial mode, the first enable signal is activated and the second enable signal is deactivated, and
wherein in the dynamic deviation reduction mode, the first enable signal and the second enable signal are activated.
